(19) United States
(12) Patent Application Publication
(10) Pub. No.: US 2026/0143594 A1
(43) Pub. Date: May 21, 2026

(54) ELECTRICAL AND ELECTRONIC COMPONENT AND METHOD OF MANUFACTURING ELECTRICAL AND ELECTRONIC COMPONENT

(71) Applicant: Alps Alpine Co., Ltd., Tokyo (JP)

(72) Inventor: Jyunichi KATO, Miyagi-ken (JP)

(21) Appl. No.: 19/447,404

(22) Filed: Jan. 13, 2026

Related U.S. Application Data
(63) Continuation of application No. PCT/JP2024/009780, filed on Mar. 13, 2024.

(30) Foreign Application Priority Data
Jul. 21, 2023 (JP) 2023-119030

(51) Int. Cl. H05K 1/181; H05K 1/11; H05K 3/30; H05K 3/341; H05K 3/3494

(52) U.S. Cl. CPC H05K 1/181; H05K 1/111; H05K 3/301; H05K 3/341; H05K 3/3494; H05K 2201/09072

(57) ABSTRACT

An electrical and electronic component includes a substrate having a mounting surface whose normal direction coincides with a first direction; and a position detection device mounted on the mounting surface. The position detection device includes a first body part fixed via a solder to a pad on the mounting surface; a second body part being displaceable relative to the first body part; a detection mechanism configured to measure a relative displacement between the first and second body parts; and a first reference part extending from the first body part and having a reference surface including a second-direction-side reference surface that faces toward one side in a second direction intersecting the first direction. The substrate includes a contact portion that is in contact with the reference surface. The contact portion includes a second-direction-side contact portion that positions the detection mechanism by being in contact with the second-direction-side reference surface.

### CLAIM OF PRIORITY

This application is a Continuation of International Application No. PCT/JP 2024/009780 filed on Mar. 13, 2024, which claims benefit of Japanese Patent Application No. 2023-119030 filed on Jul. 21, 2023. The entire contents of each application noted above are hereby incorporated by reference.

### BACKGROUND OF THE INVENTION

### 1. Field of the Invention

The present invention relates to an electrical and electronic component and a method of manufacturing an electrical and electronic component.

### 2. Description of the Related Art

As an electronic component that is appropriately mountable onto a printed circuit board, an electronic component disclosed in Japanese Unexamined Patent Application Publication No. 2009-272195 includes a housing having an opening at the front face thereof and provided with a terminal member extending rearward therefrom; and a frame including a pair of substrate-attaching pieces at positions corresponding to respective side surfaces of the housing, the frame being attached to the housing in such a manner as to cover the opening. The electronic component is to be mounted, with the aid of the terminal member and the substrate-attaching pieces, onto a printed circuit board at a cutout provided at an edge of the printed circuit board. In this electronic component, the terminal member has a flat surface portion to be brought into surface contact with a surface of the printed circuit board, and the substrate-attaching pieces are shaped in such a manner as to allow the flat surface portion to be in surface contact with the printed circuit board.

### SUMMARY OF THE INVENTION

In a process of soldering an electronic component to a substrate, the electronic component may be displaced because of the tension of molten solder. If the solder is solidified with the electronic component displaced, the position of the electronic component may vary between the one at the time of placement onto the substrate and the one after the solidification of the solder. In an electronic component configured to perform position detection, if the body (an outer surface of the case, for example) of the electronic component is taken as a reference of position detection, such a displacement of the electronic component due to soldering affects the accuracy of position detection.

The present invention provides an electrical and electronic component including a position detection device and a substrate that are appropriately positioned relative to each other, and a method of manufacturing an electrical and electronic component.

According to an aspect of the present invention, an electrical and electronic component includes a substrate having a mounting surface whose normal direction coincides with a first direction; and a position detection device mounted on the mounting surface. The position detection device includes a first body part including a first fixed portion fixed via a solder to a pad provided on the mounting surface; a second body part being displaceable relative to the first body part and at which a detection object is fixable; a detection mechanism configured to measure a relative displacement between the first body part and the second body part; and a first reference part extending from the first body part and having a reference surface whose in-plane direction coincides with the first direction. The reference surface includes a second-direction-side reference surface that faces toward one side in a second direction that is one of in-plane directions of an intersecting plane intersecting the first direction. The substrate includes a contact portion that is in contact with the reference surface. The contact portion includes a second-direction-side contact portion that positions the detection mechanism by being in contact with the second-direction-side reference surface.

With such a configuration, in a process of fixing the position detection device via the solder to the pad provided on the mounting surface of the substrate, the contact portion of the substrate and the reference surface of the position detection device come into contact with each other, and the second-direction-side contact portion of the substrate and the second-direction-side reference surface of the position detection device come into contact with each other, whereby the position detection device is appropriately positioned relative to the substrate.

In the above electrical and electronic component, the second body part may be rotatable relative to the first body part about a rotation axis extending in the first direction, and may include an engaging portion with which the detection object is engageable; the detection mechanism may be configured to measure the relative displacement in a rotation direction about the rotation axis; and the second-direction-side contact portion may serve as a positioning reference in the rotation direction about the rotation axis. Thus, the position detection device is appropriately positioned relative to the substrate in the rotation direction.

In the above electrical and electronic component, the second-direction-side contact portion may extend in a direction intersecting the first direction and the second direction. Thus, the positioning is stabilized by the surface contact between the second-direction-side reference surface and the second-direction-side contact portion.

In the above electrical and electronic component, the position detection device may further include a second reference part, the second reference part extending from a different position of the first body part from the first reference part and including an other second-direction-side reference surface facing toward the one side in the second direction; the substrate may include an other second-direction-side contact portion that positions the detection mechanism in the second direction by being in contact with the other second-direction-side reference surface; and the other second-direction-side contact portion may serve as a positioning reference for the detection mechanism in the rotation direction about the rotation axis. Thus, the position detection device is stably positioned relative to the substrate in the rotation direction.

In the above electrical and electronic component, the second-direction-side reference surface may be constituted by an outer side face of the first reference part; and the second-direction-side contact portion may be included in an inner wall of a reference hole recessed in the first direction from the mounting surface. Thus, the first reference part of the position detection device is fitted into the reference hole of the substrate, and the outer side face of the first reference part and the inner wall of the reference hole come into contact with each other, whereby the position detection device is appropriately positioned relative to the substrate.

In this case, it is preferable that, in the first reference part, a distance in the second direction between the second-direction-side reference surface and an outer side face located opposite the second-direction-side reference surface be shorter by 400 μm or more than a hole size of the reference hole in the second direction. Thus, a satisfactory clearance is produced for the process of fitting the first reference part of the position detection device into the reference hole of the substrate.

In the above electrical and electronic component, the second-direction-side reference surface may be constituted by one of two faces of the first reference part that are located opposite each other in the second direction; and the second-direction-side contact portion may be included in a wall portion of a reference protrusion protruding in the first direction from the mounting surface. Thus, the first reference part of the position detection device comes into contact with the wall portion of the reference protrusion of the substrate, whereby the position detection device is appropriately positioned relative to the substrate.

In this case, it is preferable that, in the first reference part, a distance in the second direction between the second-direction-side reference surface and an other of the two faces located opposite each other in the second direction be longer by 400 μm or more than a length of the reference protrusion in the second direction. Thus, a satisfactory clearance is produced for the process of bringing the first reference part of the position detection device into contact with the wall portion of the reference protrusion of the substrate.

In the above electrical and electronic component, the second-direction-side contact portion may be included in a side wall of a cutout that is recessed in the second direction from a side surface of the substrate. Thus, the first reference part of the position detection device comes into contact with the side wall of the cutout of the substrate, whereby the position detection device is appropriately positioned relative to the substrate.

In the above electrical and electronic component, when viewed in the first direction, a first center that is a center of the first fixed portion and a second center that is a center of the pad may coincide with each other, or the second center may be located on the one side in the second direction relative to the first center.

In this case, it is preferable that the first fixed portion of the position detection device include a plurality of first fixed portions, and the pad of the substrate include a plurality of pads provided in correspondence with the plurality of first fixed portions.

In the above electrical and electronic component, the reference surface may include a third-direction-side reference surface that faces toward one side in a third direction, the third direction being one of in-plane directions of the intersecting plane and intersecting the second direction; and the contact portion may include a third-direction-side contact portion that positions the detection mechanism relative to the substrate in the third direction by being in contact with the third-direction-side reference surface. Thus, the contact portion of the substrate and the reference surface of the position detection device come into contact with each other, the second-direction-side contact portion of the substrate and the second-direction-side reference surface of the position detection device come into contact with each other, and the third-direction-side contact portion of the substrate and the third-direction-side reference surface of the position detection device come into contact with each other, whereby the position detection device is appropriately positioned relative to the substrate.

In this case, it is preferable that, when viewed in the first direction, a first center that is a center of the first fixed portion and a second center that is a center of the pad coincide with each other, or the second center is located on the one side in the second direction and on the one side in the third direction relative to the first center.

In the above electrical and electronic component, the second-direction-side reference surface may extend in a direction intersecting the first direction and the second direction. Thus, the positioning is stabilized by the surface contact between the second-direction-side reference surface and the second-direction-side contact portion.

In the above electrical and electronic component, an end portion of the second-direction-side reference surface may be visible when viewed toward a first side in the first direction, the first side heading toward the mounting surface. Thus, in the process of mounting the position detection device onto the mounting surface of the substrate, the positioning of the first reference part is facilitated by the visibility of the end portion of the second-direction-side reference surface in the first direction.

In the above electrical and electronic component, an end portion of the other second-direction-side reference surface may be visible when viewed toward a first side in the first direction, the first side heading toward the mounting surface. Thus, in the process of mounting the position detection device onto the mounting surface of the substrate, the positioning of the second reference part is facilitated by the visibility of the end portion of the other second-direction-side reference surface in the first direction.

According to another aspect of the present invention, a method of manufacturing an electrical and electronic component, the electrical and electronic component including a substrate having a mounting surface whose normal direction coincides with a first direction; and a position detection device mounted on the mounting surface, the position detection device including a first body part including a first fixed portion fixed via a solder to a pad provided on the mounting surface; a second body part being displaceable relative to the first body part and at which a detection object is fixable; a detection mechanism configured to measure a relative displacement between the first body part and the second body part; and a first reference part extending from the first body part in a direction intersecting the first direction, the first reference part having a reference surface whose in-plane direction coincides with the first direction, the reference surface including a second-direction-side reference surface that faces toward one side in a second direction that is one of in-plane directions of an intersecting plane intersecting the first direction, the substrate including a contact portion that is in contact with the reference surface, the contact portion including a second-direction-side contact portion that positions the detection mechanism by being in contact with the second-direction-side reference surface. The method of manufacturing an electrical and electronic component includes a mounting step of mounting the position detection device onto the mounting surface of the substrate such that the pad and the first fixed portion face each other via the solder; and a reflow step of melting the solder and solidifying the molten solder such that the first fixed portion is fixed to the pad via the solder. At a completion of the mounting step, the second-direction-side reference surface and the second-direction-side contact portion are out of contact with each other; and a second center that is a center of the pad is located on the one side in the second direction relative to a first center that is a center of the first fixed portion. At a completion of the reflow step, the first center is located on the one side in the second direction relative to a position of the first center at the completion of the mounting step; and the detection mechanism is positioned with the second-direction-side reference surface and the second-direction-side contact portion being in contact with each other.

With such a method, in the mounting step of mounting the position detection device onto the mounting surface of the substrate such that the pad and the first fixed portion face each other via the solder, the second-direction-side reference surface and the second-direction-side contact portion do not need to be in contact with each other, that is, rough positioning is allowed. In the reflow step, the surface tension of the molten solder brings the second-direction-side reference surface and the second-direction-side contact portion into contact with each other, whereby the detection mechanism is positioned. In this state, the solder is solidified.

In the method of manufacturing an electrical and electronic component, the reference surface may include a third-direction-side reference surface that faces toward one side in a third direction, the third direction being one of in-plane directions of the intersecting plane and intersecting the second direction; the contact portion may include a third-direction-side contact portion that positions the detection mechanism in the third direction by being in contact with the third-direction-side reference surface; at a completion of the mounting step, the second-direction-side reference surface and the second-direction-side contact portion may be out of contact with each other, the third-direction-side reference surface and the third-direction-side contact portion may be out of contact with each other, and the second center may be located on the one side in the second direction and on the one side in the third direction relative to the first center; and at a completion of the reflow step, the first center may be located on the one side in the second direction and on the one side in the third direction relative to a position of the first center at the completion of the mounting step, and the detection mechanism may be positioned relative to the substrate in the second direction and in the third direction, with the second-direction-side reference surface and the second-direction-side contact portion being in contact with each other and the third-direction-side reference surface and the third-direction-side contact portion being in contact with each other.

Thus, in the mounting step, the second-direction-side reference surface and the second-direction-side contact portion do not need to be in contact with each other, that is, rough positioning is allowed. In the reflow step, the surface tension of the molten solder brings the second-direction-side reference surface and the second-direction-side contact portion into contact with each other and also brings the third-direction-side reference surface and the third-direction-side contact portion into contact with each other, whereby the detection mechanism is positioned. In this state, the solder is solidified.

### BRIEF DESCRIPTION OF THE DRAWINGS

FIG. 1 is a perspective view illustrating an electrical and electronic component according to the present embodiment;

FIG. 2 is a plan view illustrating the electrical and electronic component according to the present embodiment;

FIG. 3 is a side view illustrating a position detection device;

FIG. 4 is a perspective view illustrating the position detection device;

FIG. 5 is a plan view illustrating a substrate;

FIG. 6 is a diagram for describing a method of manufacturing an electrical and electronic component according to the present embodiment;

FIG. 7 is a diagram for describing the method of manufacturing an electrical and electronic component according to the present embodiment;

FIG. 8 is a diagram for describing the method of manufacturing an electrical and electronic component according to the present embodiment; and

FIGS. 9A and 9B are diagrams for describing the method of manufacturing an electrical and electronic component according to the present embodiment.

### DESCRIPTION OF THE PREFERRED EMBODIMENTS

An embodiment of the present invention will now be described in detail with reference to the accompanying drawings. In the following description, the same elements are denoted by the same reference signs, respectively, and redundant description of such elements is omitted accordingly.

### Electrical And Electronic Component

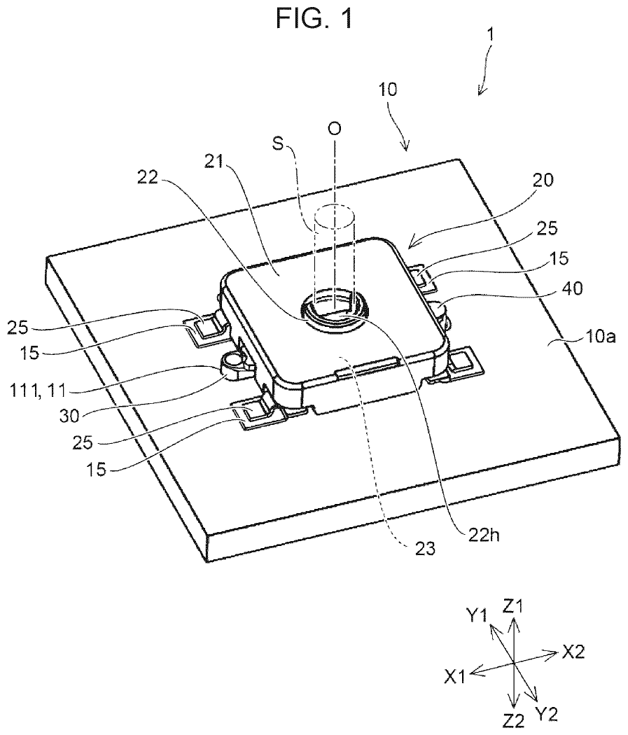

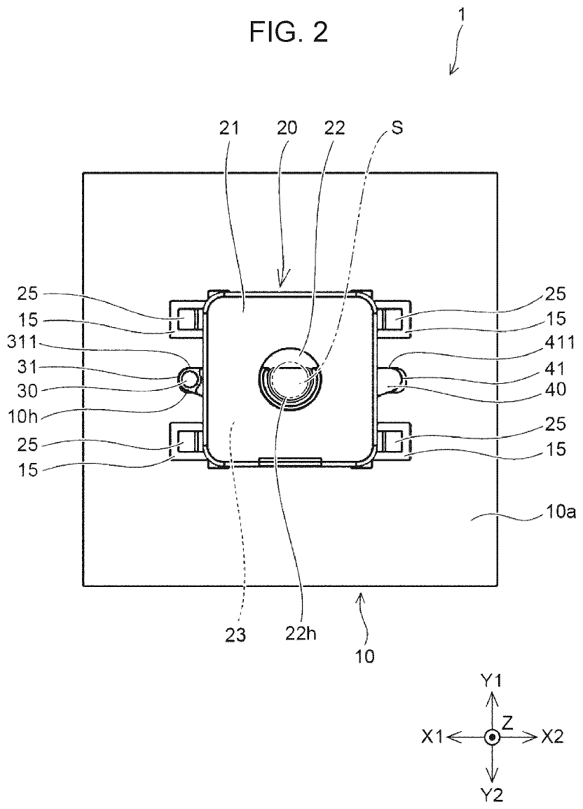

FIG. 1 is a perspective view illustrating an electrical and electronic component according to the present embodiment. FIG. 2 is a plan view illustrating the electrical and electronic component according to the present embodiment. An electrical and electronic component (hereinafter also referred to as “electronic component”) 1 according to the present embodiment includes a substrate 10 and a position detection device 20. The substrate 10 has a mounting surface 10a, whose normal direction coincides with a first direction. In the present embodiment, as one example, the first direction is denoted as the Z1-Z2 direction. The mounting surface 10a is provided with pads 15, where the position detection device 20 is to be fixed by soldering. The pads 15 are provided at such position as to face terminals 25 of the position detection device 20 to be soldered thereto.

The position detection device 20 includes a first body part 21, which includes the terminals 25 to be fixed by soldering to the respective pads 15 provided on the mounting surface 10a; and a second body part 22, which is displaceable relative to the first body part 21 and at which a detection object is fixable. In the present embodiment, the terminals 25 are each an exemplary first fixed portion. Furthermore, an example of the first body part 21 is an exterior case, and an example of the second body part 22 is a shaft-holding part rotatably provided to the case. The second body part 22 has an operation hole 22h, into which a rotary operation shaft S is fittable. With the rotation of the rotary operation shaft S, the shaft-holding part as an example of the second body part 22 rotates relative to the case as an example of the first body part 21. The rotary operation shaft S is an exemplary detection object. The operation hole 22h is an exemplary engaging portion with which the detection object is engageable. For example, if the detection object is a member having a hole, the engaging portion may be a shaft that is engageable with the hole of the member.

The position detection device 20 further includes a detection mechanism 23, which is configured to measure the relative displacement between the first body part 21 and the second body part 22. The detection mechanism 23 is accommodated in, for example, the first body part 21. The detection mechanism 23 is configured to detect the relative displacement between the first body part 21 and the second body part 22 on the basis of, for example, a change in the resistance value. The detection mechanism 23 of the position detection device 20 according to the present embodiment is configured to detect the relative displacement between the first body part 21 and the second body part 22 in a rotation direction about a rotation axis O, which extends in the first direction (Z1-Z2 direction).

The position detection device 20 includes a first reference part 30. The first reference part 30 has a reference surface 31, which extends from the first body part 21 and whose in-plane direction coincides with the first direction (Z1-Z2 direction). The reference surface 31 includes a second-direction-side reference surface 311, which faces toward one side in a second direction. The second direction is one of the in-plane directions of an intersecting plane intersecting the first direction. In the present embodiment, as one example, the second direction is denoted as the Y1-Y2 direction, and the one side in the second direction is denoted as the Y1 side.

The position detection device 20 may further include a second reference part 40, which extends from a different position of the first body part 21 from the first reference part 30. The second reference part 40 has a reference surface 41, whose in-plane direction coincides with the first direction (Z1-Z2 direction). The reference surface 41 includes an other second-direction-side reference surface 411, which faces toward the one side (Y1 side) in the second direction (Y1-Y2 direction).

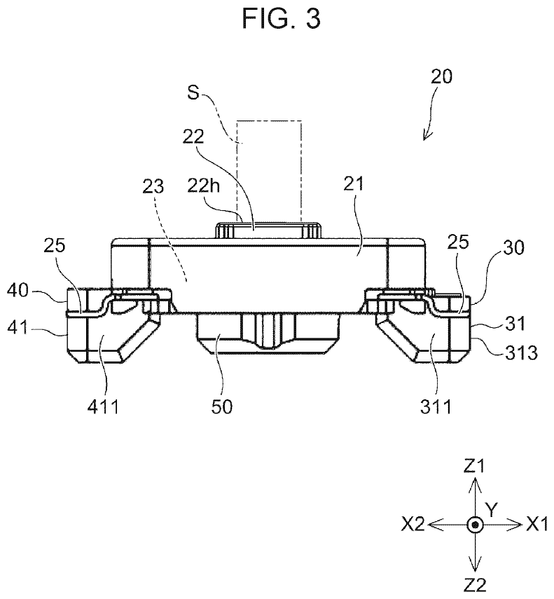

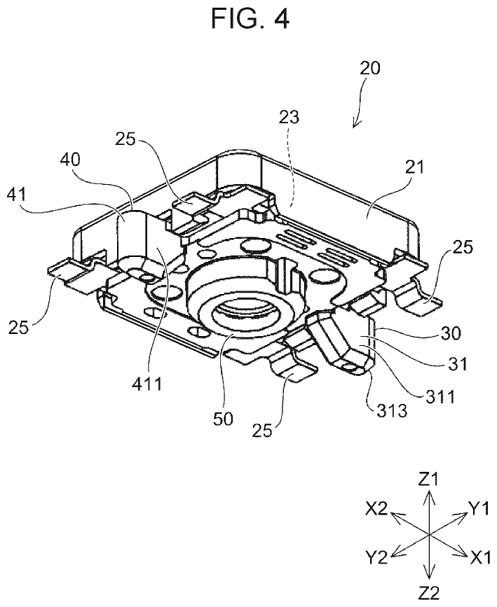

In the first reference part 30 of the position detection device 20, the reference surface 31 may include a third-direction-side reference surface 313 (see FIGS. 3 and 4), which faces toward one side in a third direction. In the present embodiment, as one example, the third direction is denoted as the X1-X2 direction, and the one side in the third direction is denoted as the X1 side.

The substrate 10 onto which the position detection device 20 configured as above is to be mounted includes a contact portion 11, which is to be in contact with the reference surface 31 of the first reference part 30 of the position detection device 20. The contact portion 11 includes a second-direction-side contact portion 111, which positions the detection mechanism 23 by coming into contact with the second-direction-side reference surface 311 of the first reference part 30 of the position detection device 20.

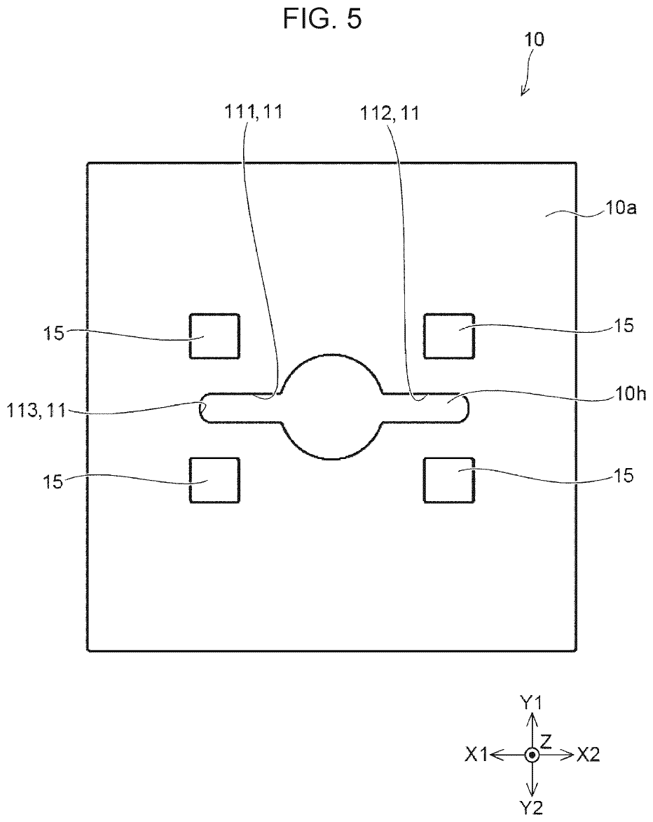

If the position detection device 20 has the other second-direction-side reference surface 411, the substrate 10 has an other second-direction-side contact portion 112 (see FIG. 5), which is to be in contact with the other second-direction-side reference surface 411. If the position detection device 20 has the third-direction-side reference surface 313, the substrate 10 has a third-direction-side contact portion 113 (see FIG. 5), which is to be in contact with the third-direction-side reference surface 313.

When the position detection device 20 is mounted onto the mounting surface 10a of the substrate 10 and is fixed by soldering to the pads 15 provided on the mounting surface 10a, the contact portion 11 of the substrate 10 and the reference surface 31 of the position detection device 20 come into contact with each other, specifically, the second-direction-side contact portion 111 of the substrate 10 and the second-direction-side reference surface 311 of the position detection device 20 come into contact with each other. Thus, the position detection device 20 is appropriately positioned relative to the substrate 10 in the second direction.

If the position detection device 20 has the other second-direction-side reference surface 411, the other second-direction-side reference surface 411 and the other second-direction-side contact portion 112 come into contact with each other. Thus, the position detection device 20 is more appropriately positioned in the rotation direction. If the position detection device 20 has the third-direction-side reference surface 313, the third-direction-side reference surface 313 comes into contact with the third-direction-side contact portion 113. Thus, the position detection device 20 is appropriately positioned in the third direction.

### Position Detection Device

FIG. 3 is a side view illustrating the position detection device. FIG. 4 is a perspective view illustrating the position detection device. In the side view illustrated in FIG. 3, the position detection device 20 is viewed from the Y1 side. In the perspective view illustrated in FIG. 4, the Y1 side and the X2 side of the position detection device 20 are viewed from the Z2 side in the Z1-Z2 direction. The terminals 25 extend, for example, laterally from the first body part 21. The lower surfaces of the terminals 25 are to face the upper surfaces of the pads 15 provided on the substrate 10 illustrated in FIG. 1. In the process of mounting the position detection device 20 onto the substrate 10, the terminals 25 are positioned face to face with the respective pads 15.

The first reference part 30 extends from the first body part 21 toward the one side (X1 side) in the third direction (X1-X2 direction), which is another one of the directions intersecting the first direction. The first reference part 30 further extends downward (the Z2 side in the Z1-Z2 direction) relative to the first body part 21. A side wall surface of the first reference part 30 serves as the reference surface 31. In the side wall surface, one (on the Y1 side) of two faces that are located opposite each other in the second direction (Y1-Y2 direction) serves as the second-direction-side reference surface 311.

It is preferable that an end portion of the second-direction-side reference surface 311 included in the first reference part 30 be visible when viewed toward a first side (Z2 side) in the first direction (Z1-Z2 direction) that heads toward the mounting surface 10a. Such a configuration facilitates, as illustrated in FIG. 2, the visual recognition (for example, recognition through image capture with a camera of a mounter) of the end portion of the second-direction-side reference surface 311 in the first direction (Z1-Z2 direction) in the process of mounting the position detection device 20 onto the mounting surface 10a of the substrate 10. Accordingly, the positioning of the first reference part 30 is facilitated.

In the side wall surface of the first reference part 30 that serves as the reference surface 31, a face that is oriented toward the one side (X1 side) in the third direction (X1-X2 direction) serves as the third-direction-side reference surface 313.

The second reference part 40 extends from a different position of the first body part 21 from the first reference part 30. For example, if the first reference part 30 extends toward the X1 side in the X1-X2 direction from the first body part 21, the second reference part 40 extends toward the X2 side in the X1-X2 direction from the first body part 21.

As one example, the second reference part 40 extends from the first body part 21 toward the other side (X2 side) in the third direction (X1-X2 direction). The second reference part 40 further extends downward (the Z2 side in the Z1-Z2 direction) relative to the first body part 21. A side wall surface of the second reference part 40 serves as the reference surface 41. In the side wall surface, one (on the Y1 side, for example) of two faces that are located opposite each other in the second direction (Y1-Y2 direction) serves as the other second-direction-side reference surface 411.

It is preferable that an end portion of the other second-direction-side reference surface 411 included in the second reference part 40 be visible when viewed toward the first side (Z2 side) in the first direction (Z1-Z2 direction) that heads toward the mounting surface 10a. Such a configuration facilitates, as illustrated in FIG. 2, the visual recognition (for example, recognition through image capture with a camera of a mounter) of the end portion of the other second-direction-side reference surface 411 in the first direction (Z1-Z2 direction) in the process of mounting the position detection device 20 onto the mounting surface 10a of the substrate 10. Accordingly, the positioning of the second reference part 40 is facilitated.

The first body part 21 may have a center protrusion 50 in a substantially central portion of the lower surface thereof (on the Z2 side in the Z1-Z2 direction). The center protrusion 50 is provided between the first reference part 30 and the second reference part 40. Such a configuration facilitates the rough positioning of the position detection device 20 in the process of mounting onto the substrate 10.

### Substrate

FIG. 5 is a plan view illustrating the substrate. The mounting surface 10a of the substrate 10 is provided with the pads 15. In the present embodiment, four pads 15 are provided in such a manner as to face four respective terminals 25 of the position detection device 20. The numbers of terminals 25 and pads 15 are not limited. The contact portion 11 of the substrate 10 includes the second-direction-side contact portion 111 that is to be in contact with the second-direction-side reference surface 311 included in the reference surface 31 of the position detection device 20.

In the present embodiment, the inner wall of the reference hole 10h that is recessed in the first direction (Z1-Z2 direction, for example) from the mounting surface 10a of the substrate 10 includes the second-direction-side contact portion 111 and the other second-direction-side contact portion 112 on the one side (Y1 side, for example) in the second direction (Y1-Y2 direction, for example). The second-direction-side contact portion 111 and the other second-direction-side contact portion 112 may extend in the third direction (X1-X2 direction, for example). The inner wall of the reference hole 10h further includes the third-direction-side contact portion 113 on the one side (X1 side) in the third direction (X1-X2 direction, for example).

Accordingly, when the first reference part 30 of the position detection device 20 is fitted into the reference hole 10h of the substrate 10, an outer side face (the second-direction-side reference surface 311) of the first reference part 30 and the second-direction-side contact portion 111 included in the inner wall of the reference hole 10h come into contact with each other, whereby the position detection device 20 is appropriately positioned relative to the substrate 10 in the second direction (Y1-Y2 direction) and in the rotation direction.

If the second-direction-side contact portion 111 of the substrate 10 extends in a direction intersecting the first direction and the second direction (for example, in the third direction (X1-X2 direction)), the positioning is stabilized by the surface contact between the second-direction-side reference surface 311 and the second-direction-side contact portion 111. That is, stopping by surface produces a higher function as a rotation stopper than stopping by line, and is more effective as a reference of positioning in the rotation direction.

Furthermore, when the second reference part 40 of the position detection device 20 is fitted into the reference hole 10h of the substrate 10, an outer side face (the other second-direction-side reference surface 411) of the second reference part 40 and the other second-direction-side contact portion 112 included in the inner wall of the reference hole 10h come into contact with each other, whereby the position detection device 20 is more appropriately positioned relative to the substrate 10 in the second direction (Y1-Y2 direction) and in the rotation direction.

If the other second-direction-side contact portion 112 of the substrate 10 extends in a direction intersecting the first direction and the second direction (for example, in the third direction (X1-X2 direction)), the positioning is stabilized by the surface contact between the other second-direction-side reference surface 411 and the other second-direction-side contact portion 112. That is, stopping by surface produces a higher function as a rotation stopper than stopping by line, and is more effective as a reference of positioning in the rotation direction.

Furthermore, when the first reference part 30 of the position detection device 20 is fitted into the reference hole 10h of the substrate 10, the third-direction-side reference surface 313 of the first reference part 30 and the third-direction-side contact portion 113 in the reference hole 10h come into contact with each other, whereby the position detection device 20 is appropriately positioned relative to the substrate 10 on the one side (X1 side) in the third direction (X1-X2 direction).

If the first body part 21 has the center protrusion 50 at the lower surface thereof, the reference hole 10h includes a portion for receiving the center protrusion 50. In the reference hole 10h, portions for receiving the first reference part 30, the second reference part 40, and the center protrusion 50 may be continuous with one another. Alternatively, any two of the three portions may be continuous with each other, or all of the three portions may be separate from each other.

The second-direction-side reference surface 311 included in the substrate 10 may alternatively be included in a wall portion of a reference protrusion (not illustrated) protruding from the mounting surface 10a in the first direction (for example, toward the Z1 side in the Z1-Z2 direction).

In the position detection device 20, the positioning reference for the detection mechanism 23 may be specified on the basis of the external shape of the position detection device 20 (absolute linearity). In such a case, the accuracy in the attaching of the position detection device 20 to the substrate 10 needs to be high, from the viewpoint of increasing the detection accuracy. Accordingly, the positioning between the position detection device 20 and the substrate 10 is implemented by fitting. However, to achieve a reduction in the size of the device and/or the automation of the attaching process, the positioning between the position detection device 20 and the substrate 10 by fitting may be difficult. Even in such a case, the present embodiment enables appropriate positioning between the position detection device 20 and the substrate 10.

### Method of Manufacturing Electrical and Electronic Component

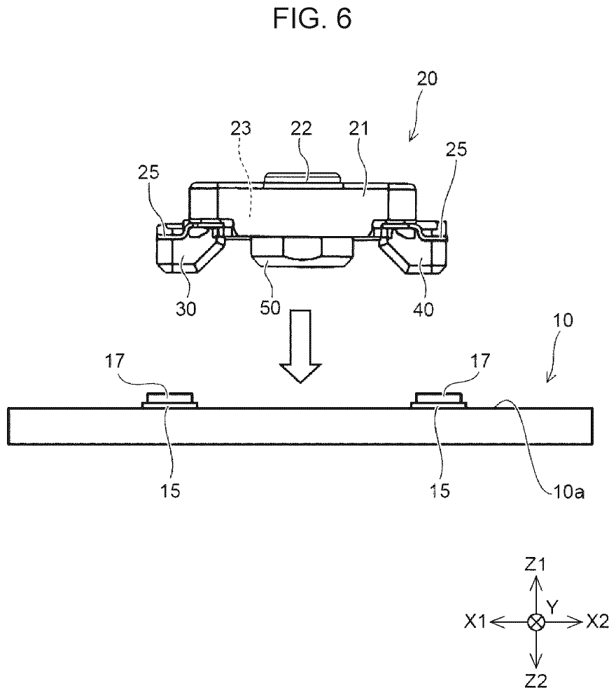

FIGS. 6 to 9 are diagrams for describing a method of manufacturing an electrical and electronic component according to the present embodiment.

First, as illustrated in FIG. 6, a substrate 10 and a position detection device 20 are prepared, and the position detection device 20 is placed onto the mounting surface 10a of the substrate 10. The pads 15 of the substrate 10 are provided with solders 17 in advance. Placing the position detection device 20 onto the mounting surface 10a of the substrate 10 brings the pads 15 and the terminals 25 to face each other via the solders 17 (a mounting step).

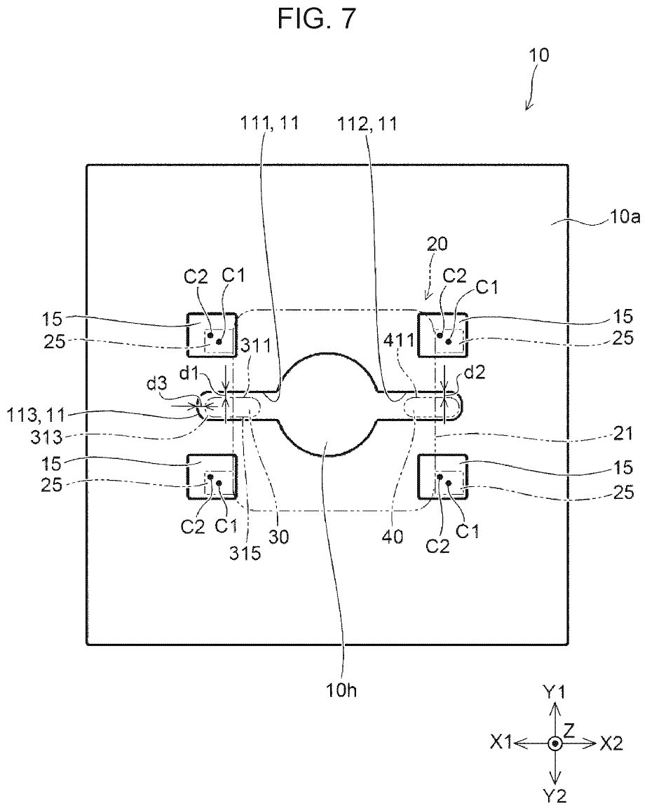

FIG. 7 illustrates the positional relationship between the substrate 10 and the position detection device 20 that is established when the position detection device 20 is placed onto the mounting surface 10a of the substrate 10. As a matter of convenience, the position detection device 20 is illustrated by a two-dot chain line. In the mounting step, when the position detection device 20 is placed onto the mounting surface 10a of the substrate 10, the first reference part 30 is fitted into the reference hole 10h of the substrate 10. Furthermore, if the position detection device 20 includes the second reference part 40, the second reference part 40 is also fitted into the reference hole 10h.

In this step, regarding the first reference part 30, the distance in the second direction (Y1-Y2 direction) between the second-direction-side reference surface 311 and an outer side face 315, which is located opposite the second-direction-side reference surface 311, is shorter than the hole size of the reference hole 10h in the second direction (Y1-Y2 direction). Specifically, it is preferable that the distance be shorter by 400 μm or more. Thus, a satisfactory clearance is produced for the process of fitting the first reference part 30 of the position detection device 20 into the reference hole 10h of the substrate 10.

In the mounting step, if the end portion of the second-direction-side reference surface 311 of the first reference part 30 and/or the end portion of the other second-direction-side reference surface 411 of the second reference part 40 is visible when viewed in the first direction (Z1-Z2 direction), the end portion is easily recognizable through, for example, image capture with a camera of a mounter. Accordingly, the positioning of the first reference part 30 and the second reference part 40 is facilitated.

In the state where the first reference part 30 is fitted in the reference hole 10h, that is, before the solders 17 are melted and solidified, the second-direction-side reference surface 311 of the first reference part 30 and the second-direction-side contact portion 111 included in the inner wall of the reference hole 10h are spaced apart from each other in the second direction (Y1-Y2 direction) (see a gap d1 illustrated in FIG. 7).

If the position detection device 20 includes the second reference part 40 and in the state where the second reference part 40 is fitted in the reference hole 10h, the other second-direction-side reference surface 311 of the second reference part 40 and the other second-direction-side contact portion 112 in the reference hole 10h are spaced apart from each other in the second direction (Y1-Y2 direction) (see a gap d2 illustrated in FIG. 7). Furthermore, if the first reference part 30 includes the third-direction-side reference surface 313, the third-direction-side reference surface 313 and the third-direction-side contact portion 113 in the reference hole 10h are spaced apart from each other in the third direction (X1-X2 direction) (see a gap d3 illustrated in FIG. 7).

That is, as illustrated in FIG. 7, at the completion of the mounting step, the first reference part 30 and the second reference part 40 are loosely fitted in the reference hole 10h. In this state, the second-direction-side reference surface 311 and the second-direction-side contact portion 111 are out of contact with each other, the other second-direction-side reference surface 411 and the other second-direction-side contact portion 112 are out of contact with each other, and the third-direction-side reference surface 313 and the third-direction-side contact portion 113 are out of contact with each other. When this state is viewed in the first direction (Z1-Z2 direction), a first center C1, which is the center of each of the terminals 25, and a second center C2, which is the center of each of the pads 15, do not coincide with each other. For example, the first center C1 is displaced from the second center C2 in an in-plane direction of the XY plane.

In the state where the first reference part 30 and the second reference part 40 are fitted in the reference hole 10h, the displacement of the position detection device 20 in a direction parallel to the mounting surface 10a (an in-plane direction of the XY plane) and the displacement of the position detection device 20 in the rotation direction about the normal to the mounting surface 10a are limited to some extent.

Subsequently, the solders 17 are melted and are then solidified, whereby the terminals 25 are fixed to the pads 15 via the solders 17 (a reflow step). When the solders 17 are melted in the reflow step, the molten solders 17 exerts a surface tension that produces a self-alignment effect with which the positions of the terminals 25 and the pads 15 are aligned relative to each other. Thus, the first centers C1 of the terminals 25 move closer to the corresponding second centers C2 of the pads 15 than at the completion of the mounting step. With this movement, the first reference part 30 of the position detection device 20 moves, whereby the second-direction-side reference surface 311 and the second-direction-side contact portion 111 come into contact with each other. With the contact between the second-direction-side reference surface 311 and the second-direction-side contact portion 111, the detection mechanism 23 is positioned. In this state, the solders 17 are solidified.

If the position detection device 20 includes the second reference part 40, the second reference part 40 moves as with the first reference part 30, whereby the other second-direction-side reference surface 411 and the other second-direction-side contact portion 112 come into contact with each other. With the contact between the first reference part 30 and the second-direction-side contact portion 111 and the contact between the second reference part 40 and the other second-direction-side contact portion 112, the position detection device 20 is more appropriately positioned not only in the XY directions but also in the rotation direction.

Furthermore, if the first reference part 30 includes the third-direction-side reference surface 313, the third-direction-side reference surface 313 and the third-direction-side contact portion 113 in the reference hole 10h come into contact with each other. Thus, the position detection device 20 is appropriately positioned on the one side (X1 side) in the third direction (X1-X2 direction).

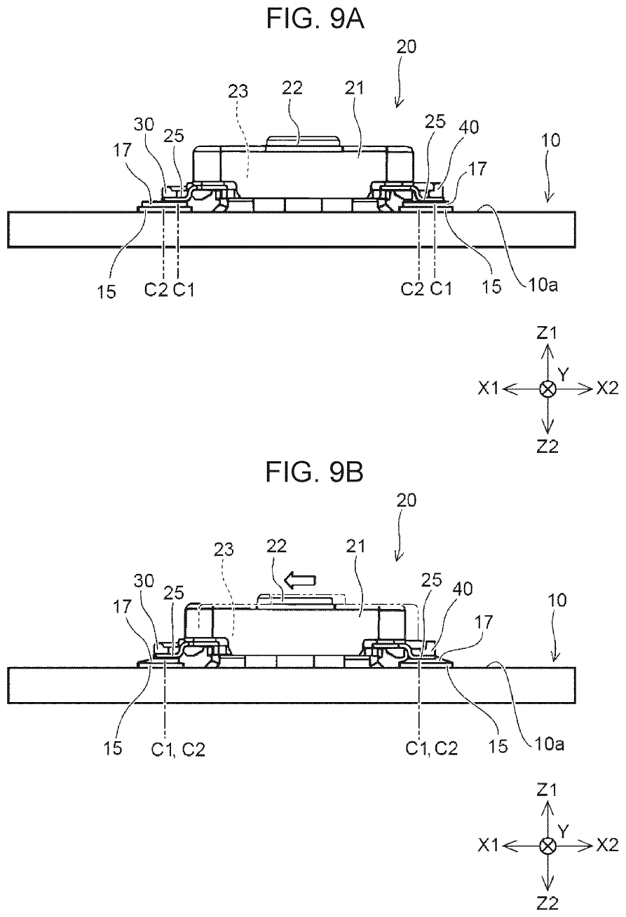

FIG. 9A is a side view illustrating the position of the position detection device 20 after the mounting step. FIG. 9B is a side view illustrating the position of the position detection device 20 after the reflow step. In the state after the mounting step that is illustrated in FIG. 9A, since the first reference part 30 and the second reference part 40 are loosely fitted in the reference hole 10h, the position of the position detection device 20 relative to the substrate 10 varies within a range of the gaps in the reference hole 10h with respect to the first reference part 30 and the second reference part 40. In this state, the first centers C1 that are the centers of the terminals 25 are displaced from the second centers C2 that are the centers of the pads 15.

In the state after the reflow step that is illustrated in FIG. 9B, the self-alignment effect produced by the surface tension of the molten solders 17 moves the position detection device 20 in such a direction that the first centers C1 of the terminals 25 coincide with the second centers C2 of the pads 15 (see the arrow illustrated in FIG. 9B). With this movement of the position detection device 20, the first reference part 30 and the second reference part 40 come into contact with the inner wall of the reference hole 10h, whereby the movement of the position detection device 20 is limited (the position detection device 20 stops moving). In this state, the solders 17 are solidified, whereby the position detection device 20 is fixed at such a position that the first centers C1 of the terminals 25 coincide with the second centers C2 of the pads 15.

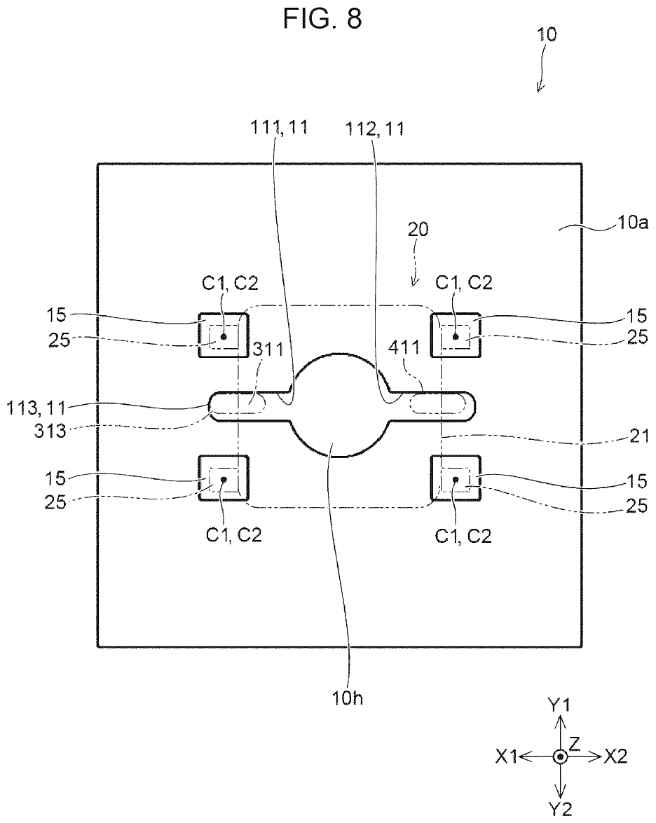

That is, according to the present embodiment, the mounting step of mounting the position detection device 20 onto the substrate 10 allows a positioning accuracy of a degree at which the first reference part 30 is loosely fitted in the reference hole 10h, whereby easy mounting is achieved. On the other hand, in the reflow step, the position detection device 20 is intentionally movable in a predetermined direction with the self-alignment effect produced by the solders 17. This movement brings the first reference part 30 and the second reference part 40 into contact with the inner wall of the reference hole 10h, whereby the position detection device 20 is appropriately positioned relative to the substrate 10. After the reflow step, the position detection device 20 is fixed at such a position that the first centers C1 (see FIG. 8) of the terminals 25 coincide with the second centers C2 (see FIG. 8) of the pads 15.

According to the present embodiment, it is possible to provide an electrical and electronic component 1 including a position detection device 20 and a substrate 10 that are appropriately positioned relative to each other, and a method of manufacturing the electrical and electronic component 1.

While the present embodiment has been described above, the present invention is not limited thereto. For example, the second-direction-side contact portion 111 may be provided at a side wall of a cutout that is recessed in the second direction from a side surface of the substrate 10. In such a case, the first reference part 30 of the position detection device 20 comes into contact with the side wall of the cutout provided in the substrate 10, whereby the position detection device 20 is appropriately positioned relative to the substrate 10. Furthermore, any addition, deletion, and design changes of relevant elements that are made to the above embodiment by those skilled in the art and any combinations of relevant features of the above embodiment that are conceived by those skilled in the art are within the scope of the present invention, as long as such embodiments include the essence of the present invention.

What is claimed is:

1. An electrical and electronic component comprising:
a substrate having a mounting surface whose normal direction coincides with a first direction; and
a position detection device mounted on the mounting surface,
wherein the position detection device includes
a first body part including a first fixed portion fixed via a solder to a pad provided on the mounting surface;
a second body part being displaceable relative to the first body part and at which a detection object is fixable;
a detection mechanism configured to measure a relative displacement between the first body part and the second body part; and
a first reference part extending from the first body part and having a reference surface whose in-plane direction coincides with the first direction,
wherein the reference surface includes a second-direction-side reference surface that faces toward one side in a second direction that is one of in-plane directions of an intersecting plane intersecting the first direction,
wherein the substrate includes a contact portion that is in contact with the reference surface, and
wherein the contact portion includes a second-direction-side contact portion that positions the detection mechanism by being in contact with the second-direction-side reference surface.

2. The electrical and electronic component according to claim 1,
wherein the second body part is rotatable relative to the first body part about a rotation axis extending in the first direction, and includes an engaging portion with which the detection object is engageable,
wherein the detection mechanism is configured to measure the relative displacement in a rotation direction about the rotation axis, and
wherein the second-direction-side contact portion serves as a positioning reference in the rotation direction about the rotation axis.

3. The electrical and electronic component according to claim 2, wherein the second-direction-side contact portion extends in a direction intersecting the first direction and the second direction.

4. The electrical and electronic component according to claim 2,
wherein the position detection device further includes a second reference part, the second reference part extending from a different position of the first body part from the first reference part and including an other second-direction-side reference surface facing toward the one side in the second direction,
wherein the substrate includes an other second-direction-side contact portion that positions the detection mechanism in the second direction by being in contact with the other second-direction-side reference surface, and
wherein the other second-direction-side contact portion serves as a positioning reference for the detection mechanism in the rotation direction about the rotation axis.

5. The electrical and electronic component according to claim 1,
wherein the second-direction-side reference surface is constituted by an outer side face of the first reference part, and
wherein the second-direction-side contact portion is included in an inner wall of a reference hole recessed in the first direction from the mounting surface.

6. The electrical and electronic component according to claim 5, wherein, in the first reference part, a distance in the second direction between the second-direction-side reference surface and an outer side face located opposite the second-direction-side reference surface is shorter by 400 μm or more than a hole size of the reference hole in the second direction.

7. The electrical and electronic component according to claim 1,
wherein the second-direction-side reference surface is constituted by one of two faces of the first reference part that are located opposite each other in the second direction, and
wherein the second-direction-side contact portion is included in a wall portion of a reference protrusion protruding in the first direction from the mounting surface.

8. The electrical and electronic component according to claim 7, wherein, in the first reference part, a distance in the second direction between the second-direction-side reference surface and an other of the two faces located opposite each other in the second direction is longer by 400 μm or more than a length of the reference protrusion in the second direction.

9. The electrical and electronic component according to claim 1, wherein the second-direction-side contact portion is included in a side wall of a cutout that is recessed in the second direction from a side surface of the substrate.

10. The electrical and electronic component according to claim 1,
wherein, when viewed in the first direction,
a first center that is a center of the first fixed portion and a second center that is a center of the pad coincide with each other, or
the second center is located on the one side in the second direction relative to the first center.

11. The electrical and electronic component according to claim 10, wherein the first fixed portion of the position detection device includes a plurality of first fixed portions, and the pad of the substrate includes a plurality of pads provided in correspondence with the plurality of first fixed portions.

12. The electrical and electronic component according to claim 1,
wherein the reference surface includes a third-direction-side reference surface that faces toward one side in a third direction, the third direction being one of in-plane directions of the intersecting plane and intersecting the second direction, and
wherein the contact portion includes a third-direction-side contact portion that positions the detection mechanism relative to the substrate in the third direction by being in contact with the third-direction-side reference surface.

13. The electrical and electronic component according to claim 12,
wherein, when viewed in the first direction,
a first center that is a center of the first fixed portion and a second center that is a center of the pad coincide with each other, or
the second center is located on the one side in the second direction and on the one side in the third direction relative to the first center.

14. The electrical and electronic component according to claim 2, wherein the second-direction-side reference surface extends in a direction intersecting the first direction and the second direction.

15. The electrical and electronic component according to claim 1, wherein an end portion of the second-direction-side reference surface is visible when viewed toward a first side in the first direction, the first side heading toward the mounting surface.

16. The electrical and electronic component according to claim 4, wherein an end portion of the other second-direction-side reference surface is visible when viewed toward a first side in the first direction, the first side heading toward the mounting surface.

17. A method of manufacturing an electrical and electronic component, the electrical and electronic component including a substrate having a mounting surface whose normal direction coincides with a first direction; and a position detection device mounted on the mounting surface,
the position detection device including
a first body part including a first fixed portion fixed via a solder to a pad provided on the mounting surface;
a second body part being displaceable relative to the first body part and at which a detection object is fixable;
a detection mechanism configured to measure a relative displacement between the first body part and the second body part; and
a first reference part extending from the first body part in a direction intersecting the first direction, the first reference part having a reference surface whose in-plane direction coincides with the first direction,
the reference surface including a second-direction-side reference surface that faces toward one side in a second direction that is one of in-plane directions of an intersecting plane intersecting the first direction,
the substrate including a contact portion that is in contact with the reference surface,
the contact portion including a second-direction-side contact portion that positions the detection mechanism by being in contact with the second-direction-side reference surface,
the method of manufacturing an electrical and electronic component comprising:
a mounting step of mounting the position detection device onto the mounting surface of the substrate such that the pad and the first fixed portion face each other via the solder; and
a reflow step of melting the solder and solidifying the molten solder such that the first fixed portion is fixed to the pad via the solder,
wherein, at a completion of the mounting step,
the second-direction-side reference surface and the second-direction-side contact portion are out of contact with each other; and
a second center that is a center of the pad is located on the one side in the second direction relative to a first center that is a center of the first fixed portion, and
wherein, at a completion of the reflow step,
the first center is located on the one side in the second direction relative to a position of the first center at the completion of the mounting step; and
the detection mechanism is positioned with the second-direction-side reference surface and the second-direction-side contact portion being in contact with each other.

18. The method of manufacturing an electrical and electronic component according to claim 17,
wherein the reference surface includes a third-direction-side reference surface that faces toward one side in a third direction, the third direction being one of in-plane directions of the intersecting plane and intersecting the second direction,
wherein the contact portion includes a third-direction-side contact portion that positions the detection mechanism in the third direction by being in contact with the third-direction-side reference surface,
wherein, at a completion of the mounting step,
the second-direction-side reference surface and the second-direction-side contact portion are out of contact with each other, and the third-direction-side reference surface and the third-direction-side contact portion are out of contact with each other; and
the second center is located on the one side in the second direction and on the one side in the third direction relative to the first center, and
wherein, at a completion of the reflow step,
the first center is located on the one side in the second direction and on the one side in the third direction relative to a position of the first center at the completion of the mounting step; and
the detection mechanism is positioned relative to the substrate in the second direction and in the third direction, with the second-direction-side reference surface and the second-direction-side contact portion being in contact with each other and the third-direction-side reference surface and the third-direction-side contact portion being in contact with each other.
